(19) United States
(12) Patent Application Publication
(10) Pub. No.: US 2022/0138560 A1
(43) Pub. Date: May 5, 2022

(54) BEHAVIOR RECOMMENDATION APPARATUS, BEHAVIOR RECOMMENDATION METHOD, AND NON-TRANSITORY COMPUTER READABLE STORAGE MEDIUM THEREOF

(71) Applicant: Institute For Information Industry, Taipei (TW)

(72) Inventors: Chien-Cheng CHYOU, Taipei (TW); Hong-En CHEN, Taipei (TW); Wei-Yu CHO, Taipei (TW); Shih-Huan HUANG, Taipei (TW); Jing-Ming CHIU, Taipei (TW)

(21) Appl. No.: 17/105,464

(22) Filed: Nov. 25, 2020

(30) Foreign Application Priority Data
Nov. 5, 2020 (TW) 109138576

(51) Int. Cl. G06N 3/08; G06F 30/20; G06N 3/04; G06F 11/34; G06F 11/30

(52) U.S. Cl. CPC G06N 3/08; G06F 30/20; G06F 11/302; G06F 11/3447; G06N 3/0454

(57) ABSTRACT

A behavior recommendation apparatus, behavior recommendation method, and non-transitory computer readable storage medium thereof are provided. The behavior recommendation apparatus stores a digital twin model, wherein the digital twin model outputs a predicted parameter set after being inputted a behavior sequence and a monitored parameter set. The behavior sequence includes a plurality of behaviors in a first sequence and quantized data. The behavior recommendation apparatus receives the monitored parameter set and an objective, wherein the objective corresponds to a particular parameter in the monitored parameter set. The behavior recommendation apparatus generates a recommended behavior sequence according to the particular parameter, the monitored parameter set, the digital twin model, and a plurality of simulated behavior sequences and displays the recommended behavior sequence on an operation interface.

### PRIORITY

This application claims priority to Taiwan Patent Application No. 109138576 filed on Nov. 5, 2020, which is hereby incorporated by reference in its entirety.

### FIELD

The present invention relates to a behavior recommendation apparatus, a behavior recommendation method, and a non-transitory computer readable storage medium thereof. Specifically, the present invention relates to an apparatus, method, and non-transitory computer readable storage medium thereof for recommending behavior sequences.

### BACKGROUND

Many fields (e.g., agriculture, forestry, fishery, animal husbandry, manufacturing, health care industry) need professionals to pass on their wisdom so that users can rely upon when performing various operations at the work site. The conventional technology mainly sorts out the standard knowledge in the field into rules and then compares the data sensed at the work site with the rules to provide behavioral guidelines. For example, when the temperature of a machine exceeds a preset temperature, it is recommended to reduce the temperature of the indoor air conditioner. This kind of conventional technology faces some difficulties as follows: the tacit knowledge and behavioral experience possessed by many professionals are difficult to be regularized, and many operational behaviors are decided to be implemented after considering many factors but not a single rule. For example, regarding machine adjustment, machine maintenance, and environmental control in factories, professionals will comprehensively consider many factors such as the environment and equipment of the factories, make various attempts on the environment and equipment (e.g., doing certain behavior(s), fine-tuning certain parameter(s), changing the sequence of certain behaviors, making different choices according to different situations), and then make adjustments according to the circumstances. Because the rules sorted out by the conventional technology do not include the tacit knowledge and behavioral experience of professionals, users often fail to achieve the desired effect when they operate at the work site by following the behavioral guidelines provided by the conventional technology.

Accordingly, there is an urgent need for a technology that can absorb the tacit knowledge and behavioral experience possessed by professionals to provide behavioral guidelines for different fields.

### SUMMARY

An objective of certain embodiments of the present invention is to provide a behavior recommendation apparatus. The behavior recommendation apparatus comprises a storage, a receiving interface, an operation interface, and a processor, and the processor is electrically connected to the storage, the receiving interface, and the operation interface. The storage stores a digital twin model, wherein the digital twin model outputs a predicted parameter set after being inputted a behavior sequence and a monitored parameter set. The behavior sequence comprises a plurality of behaviors in a first sequence and quantized data of each of the behaviors, and the predicted parameter set corresponds to the monitored parameter set. The receiving interface receives the monitored parameter set. The operation interface receives an objective, wherein the objective corresponds to a particular parameter in the monitored parameter set. The processor generates a recommended behavior sequence according to the particular parameter corresponding to the objective, the monitored parameter set, the digital twin model, and a plurality of simulated behavior sequences. The processor displays the recommended behavior sequence on the operation interface.

An objective of certain embodiments of the present invention is to provide a behavior recommendation method, which is adapted for use in an electronic computing apparatus. The electronic computing apparatus stores a digital twin model, wherein the digital twin model outputs a predicted parameter set after being inputted a behavior sequence and a monitored parameter set. The behavior sequence comprises a plurality of behaviors in a first sequence and quantized data of each of the behaviors. The predicted parameter set corresponds to the monitored parameter set. The behavior recommendation method comprises the following steps: (a) receiving the monitored parameter set, (b) receiving an objective, wherein the objective corresponds to a particular parameter in the monitored parameter set, (c) generating a recommended behavior sequence according to the particular parameter corresponding to the objective, the monitored parameter set, the digital twin model, and a plurality of simulated behavior sequences, and (d) displaying the recommended behavior sequence on an operation interface.

An objective of certain embodiments of the present invention is to provide a non-transitory computer readable storage medium, which stores a computer program comprising a plurality of codes. After an electronic computing apparatus loads the computer program, the electronic computing apparatus executes the codes of the computer program to perform a behavior recommendation method. The electronic computing apparatus stores a digital twin model. The digital twin model outputs a predicted parameter set after being inputted a behavior sequence and a monitored parameter set. The behavior sequence comprises a plurality of behaviors in a first sequence and quantized data of each of the behaviors. The predicted parameter set corresponds to the monitored parameter set. The behavior recommendation method comprises the following steps: (a) receiving the monitored parameter set, (b) receiving an objective, wherein the objective corresponds to a particular parameter in the monitored parameter set, (c) generating a recommended behavior sequence according to the particular parameter corresponding to the objective, the monitored parameter set, the digital twin model, and a plurality of simulated behavior sequences, and (d) displaying the recommended behavior sequence on an operation interface.

The behavior recommendation technology (including at least the apparatus, method, and non-transitory computer readable storage medium) provided according to certain embodiments adopts a trained digital twin model. The digital twin model outputs a predicted parameter set after being inputted a behavior sequence and a monitored parameter set. Since the behavior sequence inputted to the digital twin model comprises a plurality of behaviors in a sequence and quantized data of each of the behaviors, it means that the digital twin model generates the predicted parameter set corresponding to the behavior sequence by comprehensively considering multiple aspects (e.g., which behaviors does the behavior sequence comprise, each of the behaviors and the corresponding quantized data, and the sequence of these behaviors). The multiple aspects comprehensively considered by the digital twin model are equivalent to the tacit knowledge and behavioral experience possessed by professionals.

The behavior recommendation technology provided according to certain embodiments utilizes the digital twin model to evaluate a plurality of simulated behavior sequences from multiple aspects (e.g., which behaviors does the behavior sequence comprise, each of the behaviors and the corresponding quantized data, and the sequence of these behaviors), and then selects one of them as a recommended behavior sequence. The aforementioned operations/steps are equivalent to providing a recommended behavior sequence according to the tacit knowledge and behavioral experience possessed by professionals. Therefore, the behavior recommendation technology provided according to the present invention can solve the defect that the conventional technology provides behavioral guidelines in a rule-based manner.

The detailed technology and preferred embodiments implemented for the subject invention are described in the following paragraphs accompanying the appended drawings for people skilled in this field to well appreciate the features of the claimed invention.

### BRIEF DESCRIPTION OF THE DRAWINGS

FIG. 1A is a schematic view depicting a behavior recommendation apparatus 1 according to some embodiments;

FIG. 1B is a schematic view depicting a data flow of a digital twin model 10;

FIG. 1C is a schematic view depicting the partial data flow regarding the behavior recommendation apparatus 1 using the digital twin model 10 to evaluate simulated behavior sequences S1, S2, . . . , SK;

FIG. 1D is a schematic view depicting a specific example of a plurality of simulated behavior paths;

FIG. 1E is a schematic view depicting the partial data flow regarding the behavior recommendation apparatus 1 using historical behavior sequences H1, . . . , HP to establish the digital twin model 10;

FIG. 1F is a schematic view depicting the digital twin model 10 according to some embodiments; and

FIG. 2 is the main flowchart of a behavior recommendation method according to the present invention.

### DETAILED DESCRIPTION

In the following description, a behavior recommendation apparatus, a behavior recommendation method, and a non-transitory computer readable storage medium thereof will be explained with reference to certain example embodiments. However, these example embodiments are not intended to limit the present invention to any specific environment, applications, example or implementations described in these example embodiments. Therefore, description of these example embodiments is only for purpose of illustration rather than to limit the scope of the present invention.

It shall be appreciated that, in the following embodiments and the attached drawings, elements unrelated to the present invention are omitted from depiction. In addition, dimensions of elements and dimensional proportions among individual elements in the attached drawings are provided only for ease of depiction and illustration, but not to limit the scope of the present invention.

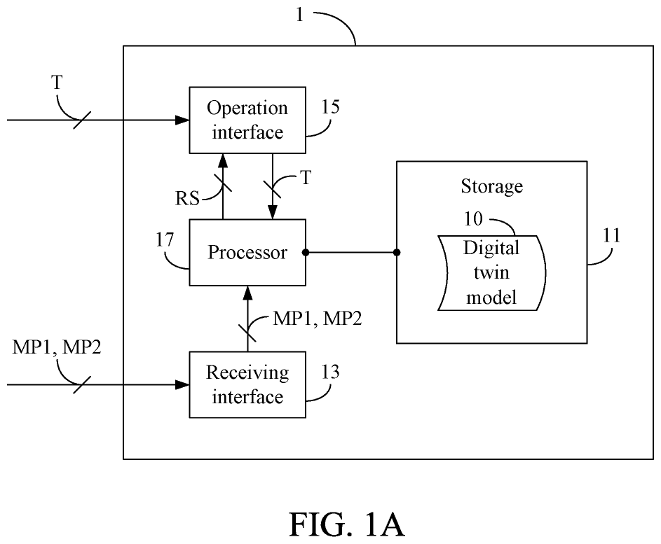

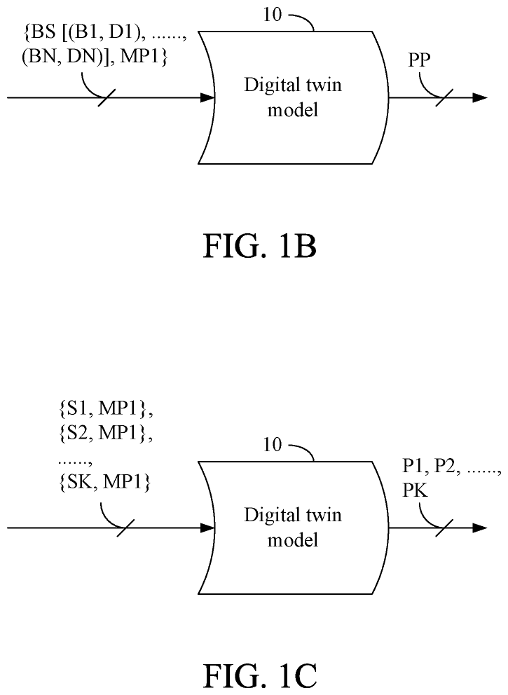

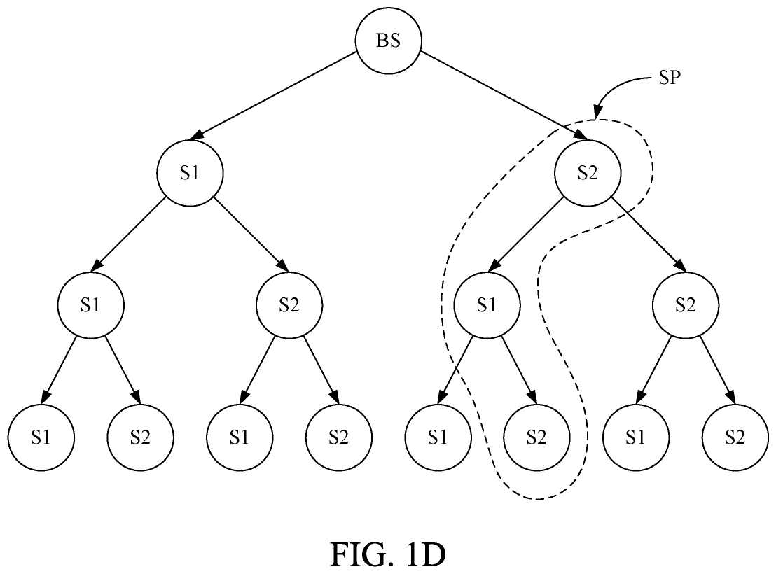

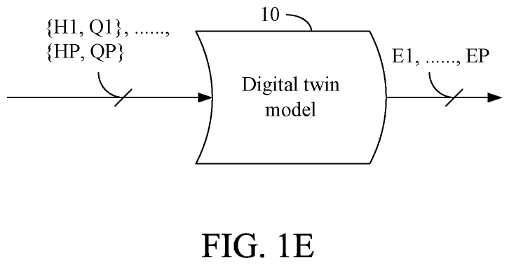

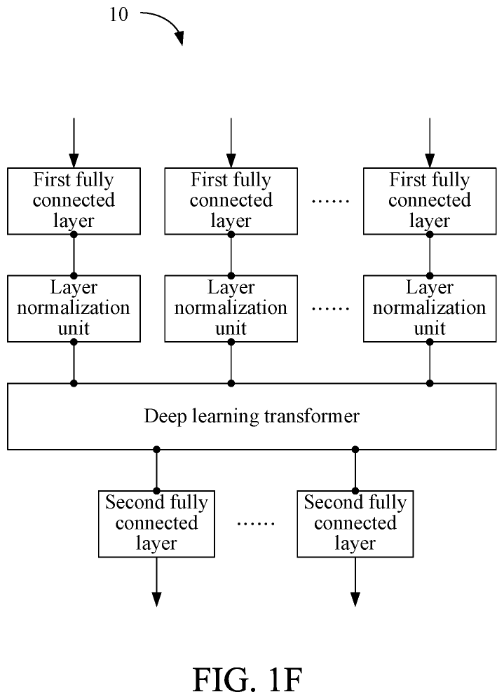

A first embodiment of the present invention is a behavior recommendation apparatus 1, and a schematic view thereof is depicted in FIG. 1A. The behavior recommendation apparatus 1 comprises a storage 11, a receiving interface 13, an operation interface 15, and a processor 17, wherein the processor 17 is electrically connected to the storage 11, the receiving interface 13, and the operation interface 15. The storage 11 may be a memory, a universal serial bus (USB) disk, a flash drive, a compact disk (CD), a digital versatile disc (DVD), a hard disk drive (HDD), or any other non-transitory storage media or apparatuses with the same function and well-known to a person having ordinary skill in the art. The receiving interface 13 may be a wired transmission interface or a wireless transmission interface known to a person having ordinary skill in the art, which is used to be connected to a network (e.g., an Internet, a local area network) and may receive and transmit signals and data over the network. The operation interface 15 may be one of various interfaces known to a person having ordinary skill in the art for users to input information and to present information for users to watch, e.g., interfaces and screens generated by computer programs, touch screens, and the like. In addition, the processor 17 may be one of various processors, central processing units (CPUs), microprocessor units (MPUs), digital signal processors (DSP), or other computing apparatuses known to a person having ordinary skill in the art.

The behavior recommendation apparatus 1 may use a digital twin model 10 to generate a recommended behavior sequence RS for a series of behaviors that need to be executed in a field or a machine, wherein the digital twin model 10 has been trained. Herein, the digital twin model 10 will be described. The storage 11 stores the digital twin model 10 related to the field or the machine, which is used to predict the result after a series of behaviors are executed in the field or the machine under a certain condition. FIG. 1B is a schematic view depicting the data flow of the digital twin model 10. As shown in FIG. 1B, after inputting a behavior sequence BS and a monitored parameter set MP1 into the digital twin model 10, the digital twin model 10 outputs a predicted parameter set PP.

Specifically, the behavior sequence BS comprises a plurality of behaviors B1, . . . , BN in a first sequence, and a plurality of quantized data D1, . . . , DN. The behaviors B1, . . . , BN correspond to the quantized data D1, . . . , DN one-to-one, which means that the execution of the behaviors B1, . . . , BN needs to follow the quantized data D1, . . . , DN respectively. Please note that if a behavior may be executed in a quantitative way (for example, how much to execute, and executing to an objective amount), the quantized data corresponding to the behavior may be the execution amount or objective amount of the behavior. If an behavior cannot be executed in a quantitative way (i.e., simply executing or not executing), the quantized data corresponding to the behavior is a preset value (e.g., 1) for indicating that the behavior should be executed or another preset value (e.g., 0) for indicating that the behavior should not be executed. In addition, the monitored parameter set MP1 comprises a plurality of parameters (e.g., environment parameters, equipment parameters) that can be monitored (e.g., sensed, measured) at the place where the field or the machine is located. The predicted parameter set PP corresponds to the monitored parameter set MP1 (that is, the predicted parameter set PP and the monitored parameter set MP1 comprise the same parameters, but the values of the parameters may be different. The values in the monitored parameter set MP1 are actually measured values, while the values in the predicted parameter set PP are values predicted by the digital twin model 10).

The digital twin model 10 predicts that the predicted parameter set PP will be obtained after the behavior sequence BS are executed in the field or the machine under the monitored parameter set MP1 (i.e., the behaviors B1, . . . , BN are executed in the first sequence, and the execution of the behaviors B1, . . . , BN follows the quantized data D1, . . . , DN respectively).

To understand the aforementioned terms, two specific examples are provided herein. Please note that the two specific examples are not intended to limit the scope of the present invention.

For example, if it is applied to a factory, each of the behaviors B1, . . . , BN may be a behavior that need to be performed in the factory such as adjusting the discharge area (the corresponding quantized data may be the value of the area to be adjusted), adjusting the discharge waveform (the corresponding quantized data may be the discharge waveform to be adjusted), and adjusting the current (the corresponding quantized data may be an adjusted current amplitude or a target current value). The behavior sequence BS may comprise all of or a part of the above behaviors and the corresponding quantized data, and the behaviors comprised in the behavior sequence BS are arranged in a certain sequence. The monitored parameter set MP1 may comprise parameters that can be monitored in the factory, e.g., expansion coefficient of the machine, oil temperature of the machine, temperature of the machine, and warm-up time of the machine.

For another example, if it is applied to a aquafarm, each of the behaviors B1, . . . , BN may be a behavior that need to be performed in the farm such as starting the waterwheel (the corresponding quantized data may be the time to start the waterwheel), feeding (the corresponding quantized data may be the amount of feed to be fed), adding minerals (the corresponding quantized data may be the amount of minerals to be added), and adding probiotics (the corresponding quantized data may be the amount of probiotics to be added). The behavior sequence BS may comprise all off or a part of the above behaviors and the corresponding quantized data, and the behaviors comprised in the behavior sequence BS are arranged in a certain sequence. The monitored parameter set MP1 may comprise parameters that can be monitored in the farm, e.g., mortality, growth status (e.g., height or weight of the creatures that are fed), and water quality data. The predicted parameter set PP and the monitored parameter set MP1 comprise the same parameters, but the values of the parameters may be different.

In the following descriptions, how the behavior recommendation apparatus 1 uses the digital twin model 10 to generate a recommended behavior sequence RS for a field or a machine that needs to perform a series of behaviors will be described.

The operation interface 15 receives an objective T, and the objective T corresponds to one or more particular parameters in the monitored parameter set MP1. The objective T may be considered as an expected goal of the user for executing a series of behaviors in the field or the machine. In some embodiments, the operation interface 15 may display a plurality of optional objectives for a user to select, the user selects one or more of the optional objectives as the objective T, and the operation interface 15 receives the objective T accordingly. For example, if it is applied to a farm, the operation interface 15 may display three optional objectives, e.g., “low mortality,” “fast growth rate,” and “feed conversion rate” (which are only used as examples, but are not intended to limit the scope of the present invention), and the user may select one or more of the three optional objectives as the objective T. If the user selects multiple optional objectives as multiple objectives T, the user may further set the ratio among the multiple objectives T. The objective T selected by the user corresponds to one or more particular parameters in the monitored parameter set MP1 (e.g., including mortality, growth status, and water quality data).

The receiving interface 13 receives the monitored parameter set MP1. The processor 17 generates a recommended behavior sequence RS according to one or more particular parameters corresponding to the objective T, the monitored parameter set MP1, the digital twin model 10, and a plurality of simulated behavior sequences S1, S2, . . . , SK, and the processor 17 displays the recommended behavior sequence RS on the operation interface 15. The simulated behavior sequences S1, S2, . . . , SK are generated based on the behaviors B1, . . . , BN (behavior sequence RS), and the simulated behavior sequences S1, S2, . . . , SK will be input into the digital twin model 10 for simulation. The recommended behavior sequence RS may be selected from the simulated behavior sequences S1, S2, . . . , SK, and the way to select recommended behavior sequence RS is based on at least one particular parameter corresponding to the objective T in the predicted parameter sets P1, P2, . . . , PK.

In some other embodiments, the objective T may be achieved through a plurality of stages (for example, a plurality of days). Thus, it is necessary to perform simulation on each stage to generate a plurality of simulated behavior sequences corresponding to each stage. In this procedure, the processor 17, based on the aforesaid approach, generates these simulated behavior sequences by arranging a plurality of behaviors that can be executed to achieve the objective T and changing different quantized data of the arranged behaviors.

Please refer to FIG. 1D for a specific example regarding the multi-stage simulation, which is an example simulated based on two simulated behavior sequences S1 and S2 and three stages (e.g., three days). The processor 17 may select one of the simulated behavior sequences S1 and S2 individually as the simulated behavior sequence in the first stage, and then individually take the predicted parameter sets (for example, the predicted parameter sets P1 and P2) generated for the simulated behavior sequences S1 and S2 by the digital twin model 10 as the monitored parameter sets MP1 in the second stage. The processor 17 generates a plurality of simulated behavior sequences S1 and S2 in the second stage according to one or more particular parameters corresponding to the objective T, the monitored parameter set MP1 of the first stage, the digital twin model 10, and the simulated behavior sequences S1 and S2. Similarly, the processor 17 generates a plurality of simulated behavior sequences S1 and S2 in the third stage according to one or more particular parameters corresponding to the objective T, the monitored parameter set MP1 of the second stage, the digital twin model 10, and the simulated behavior sequences S1 and S2. Finally, the processor 17 selects a recommended behavior sequence combination SP according to at least one particular parameter corresponding to the objective T in the predicted parameter set generated by the digital twin model 10 for the simulated behavior sequences S1 and S2 in the third stage, wherein the recommended behavior sequence combination SP comprises a plurality of recommended behavior sequences in a second sequence (i.e., simulated behavior sequences S2, S1 and S2).

In some other embodiments, although the processor 17 has generated the recommended behavior sequence combination SP of the three stages, the processor 17 may evaluate whether to regenerate the recommended behavior sequence combination after the recommended behavior sequence of each stage is executed. Specifically, after the recommended behavior sequence of the first stage (i.e., the simulated behavior sequence S2) is executed, the actual monitored parameter set MP1 may be obtained after being re-measured, the processor 17 may regenerate the predicted parameter sets (e.g., the predicted parameter sets P1 and P2) corresponding to the simulated behavior sequences S1 and S2 of the second stage according to the objective T, the actual monitored parameter set MP1, the digital twin model 10, and the simulated behavior sequences S1 and S2, and the processor 17 may adopt the similar approach to simulate the simulated behavior sequences S1 and S2 of the third stage and generate the predicted parameter set of the third stage. At this time, the processor 17 may evaluate whether to regenerate the recommended behavior sequence combination, and the result of the evaluation may be using the original recommended behavior sequence combination or replace the recommended behavior sequence of the second stage or the third stage.

In certain embodiments, the simulated behavior sequences S1, S2, . . . , SK may be preset in advance or generated in other ways. It shall be noted that each of the simulated behavior sequences S1, S2, . . . , SK comprises a plurality of behaviors in a simulation sequence and quantized data of each of the behaviors.

FIG. 1C is a schematic view depicting a part of the data flow regarding the behavior recommendation apparatus 1 using the digital twin model 10 to evaluate simulated behavior sequences S1, S2, . . . , SK. In this embodiment, the processor 17 individually inputs the simulated behavior sequences S1, S2, . . . , SK into the digital twin model 10 along with the monitored parameter set MP1, and the digital twin model 10 generates the predicted parameter sets P1, P2, . . . , PK corresponding to the simulated behavior sequences S1, S2, . . . , SK respectively. Since the objective T corresponds to one or more particular parameters in the monitored parameter set MP1 and the predicted parameter sets P1, P2, . . . , PK correspond to the monitored parameter set MP1, the processor 17 may generate the recommended behavior sequence RS according to a plurality of predicted parameters that correspond to the at least one particular parameter among the predicted parameter sets P1, P2, . . . , PK, wherein the predicted parameter sets P1, P2, . . . , PK respectively correspond to the simulated behavior sequences S1, S2, . . . , SK.

For example, the processor 17 may select one from the simulated behavior sequences S1, S2, . . . , SK as the recommended behavior sequence RS according to a preset evaluation rule corresponding to the objective T. Since the objective T corresponds to one or more particular parameters in the monitored parameter set MP1 and each of the predicted parameter sets P1, P2, . . . , PK has one or more predicted parameters corresponding to one or more particular parameters, the preset evaluation rule may be related to the one or more particular parameters (i.e., related to the one or more predicted parameters). If the objective T corresponds to a particular parameter of the monitored parameter set MP1, then the preset evaluation rule is related to the particular parameter. If the objective T corresponds to a plurality of particular parameters in the monitored parameter set MP1, then an objective ratio is set for each of the particular parameters, and the preset evaluation rule is related to these particular parameters and these objective ratios. The processor 17 may select one from the simulated behavior sequences S1, S2, . . . , SK as the recommended behavior sequence RS according to the preset evaluation rule and one or more particular parameters of each of the predicted parameter sets P1, P2, . . . , PK.

A specific example is given herein for understanding, which, however, is not intended to limit the scope of the present invention. In this specific example, the applied field is a farm, the objective T is “low mortality,” and the objective T corresponds to the particular parameter “mortality” in the monitored parameter set MP1. In this specific example, the preset evaluation rule corresponding to the objective T is related to the particular parameter “mortality”, e.g., selecting the one having the lowest mortality. The processor 17 may find out the one with the lowest mortality from the predicted parameter sets P1, P2, . . . , PK and then take the simulated behavior sequence corresponding to the one with the lowest mortality as the recommended behavior sequence RS.

Another specific example is given herein for understanding, which, however, is not intended to limit the scope of the present invention. In this specific example, the applied field is a farm, the objective T is “low mortality” and “fast growth rate,” and the objective T corresponds to the particular parameters “mortality” and “growth status” in the monitored parameter set MP1. The particular parameters “mortality” and “growth status” are respectively set to an objective ratio, e.g., 2/3 and 1/3. For each of the predicted parameter sets P1, P2, . . . , PK, the processor 17 may calculate an evaluation score according to the objective ratios and the values of the particular parameters and then select the simulated behavior sequence corresponding to the highest evaluation score as the recommended behavior sequence RS.

In some embodiments, the processor 17 generates the recommended behavior sequence RS in other ways. Specifically, the objective T may be achieved through a plurality of stages, so the processor 17 may perform simulation for each stage to generate a plurality of simulated behavior sequences corresponding to each stage. As shown in FIG. 1D, the processor 17 may generate a plurality of simulated behavior paths according to the plurality of stages, wherein each of the simulated behavior paths comprises a plurality of path nodes, the path nodes of each layer correspond to each stage, and each of the path nodes corresponds to one of a plurality of simulated behavior sequences S1, S2, . . . , SK in a sequence. It shall be noted that the present invention does not limit the number of the simulated behavior paths, nor does it limit the number of the path nodes of each simulated behavior path. FIG. 1D is a schematic view depicting a specific example of a plurality of simulated behavior paths. Please note that the tree structure is simply a way for representation, which is not intended to limit the scope of the present invention. For example, the processor 17 may use Monte Carlo tree search to generate the aforementioned tree structure. In the specific example of FIG. 1D, the processor 17 generates a plurality of simulated behavior paths from the first-level child node of the root node to any leaf node, and selects the simulated behavior paths of the simulated behavior sequences S2, S1 and S2 in the second sequence as the recommended behavior sequence combination SP according to at least one particular parameter that corresponds to the objective T among the predicted parameter set of the last-level simulated behavior sequence.

The processor 17 performs the operation (a) and the operation (b) for each of the simulated behavior paths. In the operation (a), the processor 17 inputs the simulated behavior sequences corresponding to the path nodes of a simulated behavior path and the corresponding monitored parameter set into the digital twin model 10 in sequence, and the digital twin model 10 sequentially generates the predicted parameter set of the simulated behavior sequence corresponding to each of the path nodes. The predicted parameter set of each of the path nodes is the monitored parameter set of the next path node, and the monitored parameter set of the first path node may be the monitored parameter set MP1 received by the receiving interface 13. In the operation (b), the processor 17 generates an evaluation score (not shown) of a simulated behavior path according to the predicted parameter set corresponding to the last path node in the simulated behavior path. For example, the processor 17 may calculate the evaluation score according to at least one particular parameter that corresponds to the objective T among the predicted parameter set corresponding to the last path node in a simulated behavior path. If there are multiple particular parameters, then each of the particular parameters may be weighted to calculate the evaluation score. Taking the simulated behavior path SP as an example, it comprises a plurality of path nodes, and these path nodes respectively correspond to the simulated behavior sequences S2, S1, and S2. For the simulated behavior path SP, the processor 17 inputs the simulated behavior sequences S2, S1, S2 and the corresponding monitored parameter set into the digital twin model 10 in sequence so that the digital twin model 10 sequentially generates the predicted parameter sets corresponding to the simulated behavior sequences S2, S1, S2 individually. For the simulated behavior path SP, the processor further generates the evaluation score of the simulated behavior path SP according to the predicted parameter set corresponding to the least path node.

Similarly, the processor 17 may calculate the evaluation score of each of the simulated behavior paths according to a preset evaluation rule corresponding to the objective T. As mentioned above, since the objective T corresponds to at least one particular parameter in the monitored parameter set and each predicted parameter set has at least one predicted parameter corresponding to the at least one particular parameter, the preset evaluation rule may be related to the at least one particular parameter (that is, related to the at least one predicted parameter). If the objective T corresponds to a particular parameter of the monitored parameter set, then the preset evaluation rule is related to the particular parameter. If the objective T corresponds to a plurality of particular parameters of the monitored parameter set, then an objective ratio is set for each of the particular parameters, and the preset evaluation rule is related to these particular parameters and these objective ratios. The processor 17 may generate an evaluation score according to the preset evaluation rule and the predicted parameter set of each simulated behavior path. When the objective T needs to be carried out though multiple stages, the processor 17 may generate an evaluation score for each of the simulated behavior paths according to the preset evaluation rule and the predicted parameter set corresponding to the last path node in each of the simulated behavior paths generated in each stage.

Thereafter, the processor 17 selects a simulated behavior sequence as the recommended behavior sequence RS or selects one of the simulated behavior paths as the recommended behavior sequence combination according to the evaluation scores. For example, the last path node in each of the simulated behavior paths corresponds to an evaluation score, and the processor 17 may select the simulated behavior path corresponding to the highest evaluation score as the recommended behavior sequence combination. It is noted that the selected simulated behavior path has a plurality of simulated behavior sequences in the second sequence.

As mentioned above, after the processor 17 generates the recommended behavior sequence RS, the recommended behavior sequence RS will be displayed on the operation interface 15. The recommended behavior sequence RS is one selected from a plurality of simulated behavior sequences, which comprises recommendation behaviors in a first sequence and quantized data of each of the recommendation behaviors. The recommended behavior sequence combination comprises a plurality of recommended behavior sequences in a second sequence. Thus, for each stage, the user may follow the recommended behavior sequence of that stage indicated in the recommended behavior sequence combination and execute each of the recommended behaviors of the recommended behavior sequence of that stage by following the corresponding quantized data.

In some embodiments, the behavior recommendation apparatus 1 further provides a mechanism to optimize the digital twin model 10. Specifically, the receiving interface 13 receives another monitored parameter set MP2 corresponding to the recommended behavior sequence RS being executed. The processor 17 determines whether a difference (not shown) between the monitored parameter set MP2 and the predicted parameter set corresponding to the recommended behavior sequence RS is greater than a threshold value (not shown). It may be the difference of any parameter in the monitored parameter set MP2 being greater than the corresponding threshold value. If the determination result is that the difference is greater than the threshold value, the processor 17 trains the digital twin model 10 again based on the recommended behavior sequence RS and the monitored parameter set MP2.

In this embodiment, the behavior recommendation apparatus 1 generates the digital twin model 10 and then uses the digital twin model 10 to generate the recommended behavior sequence RS. In other embodiments, the behavior recommendation apparatus 1 may utilize the digital twin model 10 generated by other apparatus with the same technology. How the behavior recommendation apparatus 1 generates the recommended behavior sequence RS will be described in detail below.

The digital twin model 10 is established by a plurality of historical behavior sequences H1, HP and a plurality of historical parameter sets Q1, . . . , QP corresponding thereto. Please refer to FIG. 1E, which is a schematic view depicting the partial data flow regarding the behavior recommendation apparatus 1 using the historical behavior sequences H1, . . . , HP to establish the digital twin model 10. For each of the historical behavior sequences H1, . . . , HP, the behavior recommendation apparatus 1 performs the following operations: inputting, by the processor 17, the historical behavior sequence and the corresponding historical parameter set into the digital twin model 10 so that the digital twin model 10 generates a historical predicted parameter set of the historical behavior sequence; receiving, by the receiving interface 13, a historical monitored parameter set after the historical behavior sequence is executed; calculating, by the processor 17, a difference between the historical monitored parameter set and the historical predicted parameter set; and adjusting, by the processor 17, the digital twin model 10 according to the difference.

Taking the historical behavior sequence H1 as an example, the processor 17 inputs the historical behavior sequence H1 and the corresponding historical parameter set Q1 into the digital twin model 10, the digital twin model 10 generates a historical predicted parameter set E1 of the historical behavior sequence H1, the receiving interface 13 receives a historical monitored parameter set (not shown) after the historical behavior sequence H1 is executed, the processor 17 calculates a difference between the historical monitored parameter set and the historical predicted parameter set E1, and the processor 17 adjusts the digital twin model 10 according to the difference. Taking the historical behavior sequence HP as another example, the processor 17 inputs the historical behavior sequence HP and the corresponding historical parameter set QP into the digital twin model 10, the digital twin model 10 generates a historical predicted parameter set EP of the historical behavior sequence HP, the receiving interface 13 receives a historical monitored parameter set (not shown) after the historical behavior sequence HP is executed, the processor 17 calculates a difference between the historical monitored parameter set and the historical predicted parameter set EP, and the processor 17 adjusts the digital twin model 10 according to the difference.

In some embodiments, the digital twin model 10 may adopt the architecture shown in FIG. 1F. In these embodiments, the digital twin model 10 may comprise a plurality of first fully connected layers, a plurality of layer normalization units, a transformer of deep learning technology, and a plurality of second fully connected layers, wherein the first fully connected layers are connected to the layer normalization units one to one, the layer normalization units are connected to the transformer of deep learning technology, and the transformer of deep learning technology is connected to the second fully connected layers. In these embodiments, the behaviors B1, . . . , BN comprised in the behavior sequence BS, quantized data D1, DN and the parameters comprised in the monitored parameter set MP1 are individually input into a first fully connected layer, while the parameters comprised in the predicted parameter set PP are individually output from a second fully connected layer.

According to the above description, the behavior recommendation apparatus 1 utilizes the trained digital twin model 10 to generate the recommended behavior sequence RS. The digital twin model 10 outputs the predicted parameter set PP after being inputted the behavior sequence BS and the monitored parameter set MP1. Since the behavior sequence BS inputted to the digital twin model 10 comprises behaviors B1, . . . , BN in a sequence and quantized data D1, . . . , DN corresponding to the behaviors respectively, it means that the digital twin model 10 generates the predicted parameter set PP corresponding to the behavior sequence BS by comprehensively considering multiple aspects (e.g., which behaviors does the behavior sequence BS comprise, each of the behaviors and the quantized data corresponding thereto, and the sequence of these behaviors). The multiple aspects comprehensively considered by the digital twin model 10 are equivalent to the tacit knowledge and behavioral experience possessed by professionals. The behavior recommendation apparatus 1 uses the digital twin model 10 to evaluate a plurality of simulated behavior sequences S1, S2, . . . , SK from multiple aspects and then selects one of them as the recommended behavior sequence RS. The operations executed by the behavior recommendation apparatus 1 are equivalent to providing the recommended behavior sequence RS according to the tacit knowledge and behavioral experience possessed by professionals. Therefore, the behavior recommendation apparatus 1 can solve the defect that the conventional technology provides behavioral guidelines in a rule-based manner.

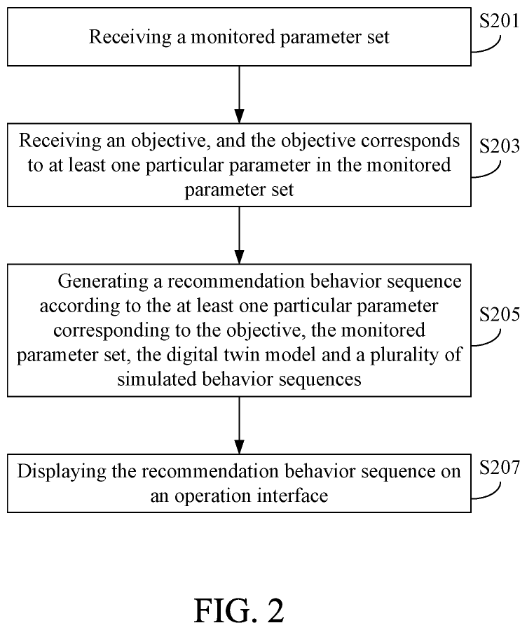

A second embodiment of the present invention is a behavior recommendation method, and a main flowchart thereof is depicted in FIG. 2. The behavior recommendation method is adapted for use in an electronic computing apparatus (e.g., the behavior recommendation apparatus 1), and the electronic computing apparatus stores a digital twin model. The digital twin model outputs a predicted parameter set after being inputted a behavior sequence and a monitored parameter set, wherein the behavior sequence comprises a plurality of behaviors in a first sequence and quantized data of each of the behaviors. The predicted parameter set corresponds to the monitored parameter set. In this embodiment, the behavior recommendation method comprises steps S201 to S207.

At the step S201, the electronic computing apparatus receives the monitored parameter set. At the step S203, the electronic computing apparatus receives an objective, wherein the objective corresponds to at least one particular parameter in the monitored parameter set. In some embodiments, if the objective corresponds to a plurality of particular parameters of the monitored parameter set, an objective ratio may be set for each of the particular parameters. It shall be noted that the present invention does not limit the execution order of the step S201 and the step S203. In other words, the behavior recommendation method may execute the step S201 and then execute the step S203, may execute the step S203 and then execute the step S201, or may execute the step S201 and the step S203 simultaneously.

In the step S205, the electronic computing apparatus generates a recommended behavior sequence according to the at least one particular parameter corresponding to the objective, the monitored parameter set, the digital twin model, and a plurality of simulated behavior sequences.

In some embodiments, before executing the step S205, the behavior recommendation method will execute another step to generate the simulated behavior sequences by arranging a plurality of behaviors of the behavior sequence and changing different quantized data of the arranged behaviors, and select one of them as the recommended behavior sequence combination. The implementation details of the procedures related to evaluating rules, generating simulated behavior paths and recommended behavior sequence combination, the operation interface, training and optimizing the digital twin model, or the like are the same as those of the previous embodiments. Thus, the details will not be further described herein.

In some embodiments, the digital twin model comprises a plurality of first fully connected layers, a plurality of layer normalization units, a transformer of deep learning technology, and a plurality of second fully connected layers, wherein the first fully connected layers are connected to the layer normalization units one to one, the layer normalization units are connected to the transformer of deep learning technology, and the transformer of deep learning technology is connected to the second fully connected layers. In these embodiments, the behaviors comprised in the behavior sequence, the quantized data, and a plurality of parameters comprised in the monitor parameter set are individually input into a first fully connected layer, while a plurality of parameters comprised in the predicted parameter set are individually output from a second fully connected layer.

In addition to the aforesaid steps, the second embodiment can also execute all the operations and steps that can be executed by the behavior recommendation apparatus 1, have the same functions, and deliver the same technical effects as the behavior recommendation apparatus 1. How the second embodiment executes these operations and steps, has the same functions, and delivers the same technical effects as the behavior recommendation apparatus 1 will be readily appreciated by a person having ordinary skill in the art based on the above explanation of the behavior recommendation apparatus 1, and thus will not be further described herein.

The behavior recommendation method described in the second embodiment may be implemented as a computer program having a plurality of codes. The computer program may be stored in a non-transitory computer readable storage medium. After the codes comprised in the computer program are loaded into an electronic computing apparatus (e.g., the behavior recommendation apparatus 1), the computer program executes the behavior recommendation method as described in the second embodiment. The non-transitory computer readable storage medium may be an electronic product, e.g., a read only memory (ROM), a flash memory, a floppy disk, a hard disk, a compact disk (CD), a digital versatile disc (DVD), a mobile disk, a database accessible to networks, or any other storage medium with the same function and well known to a person having ordinary skill in the art.

It shall be noted that, in the specification and the claims of the present invention, some words (including sequence, fully connected layer) are preceded by terms such as “first” or “second,” and these terms of “first” and “second” are used to distinguish these words from each other.

The behavior recommendation technology (including at least the apparatus, method, and non-transitory computer readable storage medium) provided according to the present invention adopts a trained digital twin model. The digital twin model outputs a predicted parameter set after being inputted a behavior sequence and a monitored parameter set. Since the behavior sequence inputted to the digital twin model comprises a plurality of behaviors in a sequence and quantized data of each of the behaviors, it means that the digital twin model generates the predicted parameter set corresponding to the behavior sequence by comprehensively considering multiple aspects (e.g., which behaviors does the behavior sequence comprise, each of the behaviors and the quantized data corresponding thereto, and the sequence of these behaviors). The multiple aspects comprehensively considered by the digital twin model are equivalent to tacit knowledge and behavioral experience possessed by professionals.

The behavior recommendation technology provided according to the present invention utilizes the digital twin model to evaluate a plurality of simulated behavior sequences from multiple aspects (e.g., which behaviors the behavior sequence comprises, each of the behaviors and the quantized data corresponding thereto, and the sequence of these behaviors), and then selects one of them as a recommended behavior sequence. The aforementioned operations/steps are equivalent to providing a recommended behavior sequence according to the tacit knowledge and behavioral experience possessed by professionals. Therefore, the behavior recommendation technology provided according to the present invention can solve the defect that the conventional technology provides behavioral guidelines in a rule-based manner.

The above disclosure is related to the detailed technical contents and inventive features thereof. People skilled in this field may proceed with a variety of modifications and replacements based on the disclosures and suggestions of the invention as described without departing from the characteristics thereof. Nevertheless, although such modifications and replacements are not fully disclosed in the above descriptions, they have substantially been covered in the following claims as appended.

What is claimed is:

1. A behavior recommendation apparatus, comprising:
a storage, being configured to store a digital twin model, wherein the digital twin model outputs a predicted parameter set after being inputted a behavior sequence and a monitored parameter set, the behavior sequence comprises a plurality of behaviors in a first sequence and quantized data of each of the behaviors, and the predicted parameter set corresponds to the monitored parameter set;
a receiving interface, being configured to receive the monitored parameter set;
an operation interface, being configured to receive an objective, wherein the objective corresponds to a particular parameter in the monitored parameter set; and
a processor, being electrically connected to the storage, the receiving interface, and the operation interface, and being configured to generate a recommended behavior sequence according to the particular parameter corresponding to the objective, the monitored parameter set, the digital twin model, and a plurality of simulated behavior sequences and display the recommended behavior sequence on the operation interface.

2. The behavior recommendation apparatus of claim 1, wherein the processor further inputs each of the simulated behavior sequences and the monitored parameter set into the digital twin model so that the digital twin model generates a predicted parameter set of each of the simulated behavior sequences individually, and the processor generates the recommended behavior sequence according to a plurality of predicted parameters corresponding to the particular parameter in the predicted parameter sets of the simulated behavior sequences.

3. The behavior recommendation apparatus of claim 1, wherein the processor further generates a plurality of simulated behavior sequences for each of a plurality of stages and then generates a recommended behavior sequence combination according to the simulated behavior sequences of the last stage, wherein the recommended behavior sequence combination comprises a plurality of recommended behavior sequences corresponding to a second sequence.

4. The behavior recommendation apparatus of claim 3, wherein the processor further generates a plurality of simulated behavior paths according to the stages, each of the simulated behavior paths comprises a plurality of path nodes, each of the path nodes corresponds to one of the simulated behavior sequences, each of the simulated behavior paths comprises a plurality of simulated behavior sequences in a third sequence, and the processor performs the following operations individually for each of the simulated behavior paths:
(a) inputting the simulated behavior sequences corresponding to the path nodes of the simulated behavior path and the corresponding monitored parameter set into the digital twin model in sequence so that the digital twin model sequentially generates the predicted parameter set of the simulated behavior sequence corresponding to each of the path nodes, wherein the predicted parameter set of each of the path nodes is the monitored parameter set of the next path node, and
(b) generating an evaluation score of the simulated behavior path according to the predicted parameter set corresponding to the last path node in the simulated behavior path,
wherein the processor further selects the simulated behavior sequences corresponding to one of the simulated behavior paths as the recommended behavior sequence combination according to the evaluation scores.

5. The behavior recommendation apparatus of claim 1, wherein the processor selects one of the simulated behavior sequences as the recommended behavior sequence according to a preset evaluation rule corresponding to the objective.

6. The behavior recommendation apparatus of claim 1, wherein the receiving interface further receives another monitored parameter set corresponding to the recommended behavior sequence being executed,
wherein the processor trains the digital twin model again based on the recommended behavior sequence and the another monitored parameter set when the processor determines that a difference between the another monitored parameter set and the predicted parameter set corresponding to the recommended behavior sequence is greater than a threshold value.

7. The behavior recommendation apparatus of claim 1, wherein the digital twin model is established by a plurality of historical behavior sequences and a plurality of corresponding historical parameter sets, and for each of the historical behavior sequences:
the processor inputs the historical behavior sequence and one of the historical parameter sets into the digital twin model so that the digital twin model generates a historical predicted parameter set of the historical behavior sequence, and the receiving interface receives a historical monitored parameter set after the historical behavior sequence is executed,
the processor further calculates a difference between the historical monitored parameter set and the historical predicted parameter set, and
the processor further adjusts the digital twin model according to the difference.

8. The behavior recommendation apparatus of claim 1, wherein the digital twin model comprises a plurality of first fully connected layers, a plurality of layer normalization units, a transformer of deep learning technology, and a plurality of second fully connected layers, wherein the first fully connected layers are connected to the layer normalization units one to one, the layer normalization units are connected to the transformer, and the transformer is connected to the second fully connected layers.

9. The behavior recommendation apparatus of claim 1, wherein the objective corresponds to a plurality of particular parameters of the monitored parameter set, and an objective ratio is set for each of the particular parameters.

10. The behavior recommendation apparatus of claim 1, wherein the processor generates the simulated behavior sequences by arranging a plurality of behaviors of the behavior sequence and changing different quantized data of the arranged behaviors.

11. A behavior recommendation method, being adapted for use in an electronic computing apparatus, the electronic computing apparatus storing a digital twin model, the digital twin model outputting a predicted parameter set after being inputted a behavior sequence and a monitored parameter set, the behavior sequence comprising a plurality of behaviors in a first sequence and quantized data of each of the behaviors, the predicted parameter set corresponding to the monitored parameter set, the behavior recommendation method comprising:
(a) receiving the monitored parameter set;
(b) receiving an objective, wherein the objective corresponds to a particular parameter in the monitored parameter set;
(c) generating a recommended behavior sequence according to the particular parameter corresponding to the objective, the monitored parameter set, the digital twin model, and a plurality of simulated behavior sequences; and
(d) displaying the recommended behavior sequence on an operation interface.

12. The behavior recommendation method of claim 11, wherein the step (c) comprises:
inputting each of the simulated behavior sequences and the monitored parameter set into the digital twin model so that the digital twin model generates a predicted parameter set of each of the simulated behavior sequences individually; and
generating the recommended behavior sequence according to a plurality of predicted parameters corresponding to the particular parameter in the predicted parameter sets of the simulated behavior sequences.

13. The behavior recommendation method of claim 12, wherein the step (c) comprises:
generating a plurality of simulated behavior sequences for each of a plurality of stages; and
generating a recommended behavior sequence combination according to the simulated behavior sequences of the last stage, wherein the recommended behavior sequence combination comprises a plurality of recommended behavior sequences corresponding to a second sequence.

14. The behavior recommendation method of claim 13, wherein the step (c) comprises:
generating a plurality of simulated behavior paths according to the stages, wherein each of the simulated behavior paths comprises a plurality of path nodes, each of the path nodes corresponds to one of the simulated behavior sequences, and each of the simulated behavior paths comprises a plurality of simulated behavior sequences in a third sequence;
executing the following steps for each of the simulated behavior paths individually:
inputting the simulated behavior sequences corresponding to the path nodes of the simulated behavior path and the corresponding monitored parameter set into the digital twin model in sequence so that the digital twin model sequentially generates the predicted parameter set of the simulated behavior sequence corresponding to each of the path nodes, wherein the predicted parameter set of each of the path nodes is the monitored parameter set of the next path node; and
generating an evaluation score of the simulated behavior path according to the predicted parameter set corresponding to the last path node in the simulated behavior path; and
selecting the simulated behavior sequences corresponding to one of the simulated behavior paths as the recommended behavior sequence combination according to the evaluation scores.

15. The behavior recommendation method of claim 11, wherein the step (c) selects one of the simulated behavior sequences as the recommended behavior sequence according to a preset evaluation rule corresponding to the objective.

16. The behavior recommendation method of claim 11, further comprising:
receiving another monitored parameter set corresponding to the recommended behavior sequence being executed; and
training the digital twin model again based on the recommended behavior sequence and the another monitored parameter set when the processor determines that a difference between the another monitored parameter set and the predicted parameter set corresponding to the recommended behavior sequence is greater than a threshold value.

17. The behavior recommendation method of claim 11, wherein the digital twin model is established by a plurality of historical behavior sequences and a plurality of corresponding historical parameter sets, the behavior recommendation method further comprising:
performing the following steps for each of the historical behavior sequences:
inputting the historical behavior sequence and one of the historical parameter sets into the digital twin model so that the digital twin model generates a historical predicted parameter set of the historical behavior sequence;
receiving a historical monitored parameter set after the historical behavior sequence is executed;
calculating a difference between the historical monitored parameter set and the historical predicted parameter set; and
adjusting the digital twin model according to the difference by the processor.

18. The behavior recommendation method of claim 11, wherein the digital twin model comprises a plurality of first fully connected layers, a plurality of layer normalization units, a transformer of deep learning technology, and a plurality of second fully connected layers, wherein the first fully connected layers are connected to the layer normalization units one to one, the layer normalization units are connected to the transformer, and the transformer is connected to the second fully connected layers.

19. The behavior recommendation method of claim 11, further comprising:
generating the simulated behavior sequences by arranging a plurality of behaviors of the behavior sequence and changing different quantized data of the arranged behaviors.

20. A non-transitory computer readable storage medium, storing a computer program comprising a plurality of codes, the computer program executing a behavior recommendation method after the codes are loaded into an electronic computing apparatus, the electronic computing apparatus storing a digital twin model, the digital twin model outputting a predicted parameter set after being inputted a behavior sequence and a monitored parameter set, the behavior sequence comprising a plurality of behaviors in a first sequence and quantized data of each of the behaviors, the predicted parameter set corresponding to the monitored parameter set, the behavior recommendation method comprising:
(a) receiving the monitored parameter set;
(b) receiving an objective, wherein the objective corresponds to a particular parameter in the monitored parameter set;
(c) generating a recommended behavior sequence according to the particular parameter corresponding to the objective, the monitored parameter set, the digital twin model, and a plurality of simulated behavior sequences; and
(d) displaying the recommended behavior sequence on an operation interface.
